(19) United States
(12) Patent Application Publication
(10) Pub. No.: US 2022/0399466 A1
(43) Pub. Date: Dec. 15, 2022

(54) GRAPHENE PHOTODETECTOR AND PHOTODETECTOR ARRAY USING SAME

(71) Applicant: KEIO UNIVERSITY, Tokyo (JP)

(72) Inventors: Hideyuki MAKI, Kanagawa (JP); Kenta SIMOMURA, Kanagawa (JP)

(21) Appl. No.: 17/754,268

(22) PCT Filed: Sep. 29, 2020
(86) PCT No.: PCT/JP2020/036834

§ 371 Date: Mar. 29, 2022

(30) Foreign Application Priority Data
Sep. 30, 2019 (JP) 2019-178844

(51) Int. Cl. H01L 31/0216; H01L 31/09; H01L 27/144; H01L 31/0224

(52) U.S. Cl. CPC H01L 31/02164; H01L 31/09; H01L 27/1446; H01L 31/0224; H01L 31/028

(57) ABSTRACT

In a graphene photodetector, in which a graphene film is electrically connected a first electrode and to a second electrode, the first electrode and the second electrode are formed of the same conductive material, and the first electrode and the second electrode have an asymmetric structure in interface regions with the graphene film.

### TECHNICAL FIELD

The present invention relates to a graphene photodetector and a method for manufacturing the same.

### BACKGROUND ART

Graphene is a two-dimensional material having a structure of a series of six-membered carbon rings and a layer with a thickness of a single atom. Since the graphene has a property of absorbing light at a constant absorption coefficient irrespective of a wavelength according to a linear band dispersion, it is known that a photodetector using a graphene film as a light receiving layer can accommodate a wide wavelength range. In addition, it is known that the graphene film can be fabricated on a variety of substrates including a silicon substrate, and a high-speed photodetector can be obtained.

A photodetector can be fabricated by connecting a pair of electrodes to a graphene film. In this case, a gradient occurs in an energy band at an electrode-graphene film interface due to differences between work functions of the metal electrode and of the graphene. The directions of the gradient are opposite to each other between the electrodes so that photovoltages or photocurrents generated by light incidence are cancelled with each other.

FIG. 1 is a diagram illustrating cancellation of photovoltages or photocurrents occurring in a typical graphene photodetector. When the entire graphene photodetector, in which a graphene film G is placed between two electrodes EL, is irradiated, electrons or holes are generated at an electrode-graphene film interface, and a photovoltage is generated only near the interface. As shown in (a) of FIG. 1, the polarity of the photovoltage generated at the interface between one electrode and the graphene film and the polarity of the photovoltage generated at the interface between the other electrode and the graphene film are opposite to each other, and the photovoltages cancel each other. Thus, the sensitivity of the photodetector is significantly reduced.

As shown in (b) of FIG. 1, when a circuit connection is made between the two electrodes EL, photocurrents flow. At the electrode-graphene film interface, electrons move along a gradient of a conduction band, and photocurrents flow in opposite directions to each other, as indicated by arrows I, and cancel each other.

Thus, when light enters the entire graphene photodetector, the photovoltage generated at the electrode-graphene film interface, or the photocurrent observed between the two electrodes, is very small or nearly zero.

Techniques have been reported in which two electrodes are formed of metals with different work functions to reduce the cancellation in photovoltages between the electrodes and to detect light without a light collecting mechanism (see, for example, Non-Patent Document 1).

### CITATION LIST

### Non-Patent Literature

Non-Patent Document 1: Thomas Mueller, Fengnian Xia and Phaedon Avouris, Graphene photodetectors for high-speed optical communications, Nature Photonics, 2010, 4, 297

### SUMMARY OF INVENTION

### Problem to be Solved by the Invention

In a conventional graphene photodetector, in order to detect light, light entering the photodetector needs to be collected by lens and only the vicinity of one electrode needs to be irradiated. Near-infrared light and mid-infrared light cannot be sensed by a naked eye or a silicon-based imaging device, so that it is difficult to focus such light and to cause only the vicinity of one electrode to be irradiated.

In the method of forming electrodes with metals having different work functions, the device fabrication process is complicated because the electrodes are formed separately with different metallic materials. In addition, a precious metal material such as Pd or Au is used as the electrode material having a “high” work function, which increases the cost. As the electrode material having a “low” work function, a metal that is easily oxidized, such as Ca, Mg, or Sc, is used, and device damage due to oxidation is likely to occur. Metals with low work functions are also expensive, and the cost may increase depending on the material.

An object of the present invention is to provide a graphene photodetector capable of light detection without light collection and an array of photodetectors using the graphene photodetector.

### Means for Solving the Problem

In a graphene photodetector, in which a graphene film is electrically connected a first electrode and to a second electrode, the first electrode and the second electrode are formed of the same conductive material, and the first electrode and the second electrode have an asymmetric structure in interface regions with the graphene film.

As an example of the asymmetric structure, either the first electrode or the second electrode is covered with a light shielding mask in the interface region with the graphene film.

As another example of the asymmetric structure, the first electrode and the second electrode have different planar shapes in the interface region.

### Effects of the Invention

The cancellation of photovoltages or photocurrents generated in the graphene photodetector is suppressed, thus allowing light can be detected without light collection.

### BRIEF DESCRIPTION OF DRAWINGS

FIG. 1 is a diagram illustrating a cancellation of photovoltages or photocurrents generated when an entire graphene photodetector is irradiated.

FIG. 2 is a diagram illustrating a basic configuration according to a first embodiment.

FIG. 3A is an image of a graphene photodetector according to the first embodiment captured by an optical microscope.

FIG. 3B is a cross-sectional view schematically illustrating the graphene photodetector according to the first embodiment.

FIG. 4A is a diagram illustrating an example of an operation principle of the graphene photodetector according to the first embodiment.

FIG. 4B is a diagram illustrating another example of the operation principle of the graphene photodetector according to the first embodiment.

FIG. 4C is a diagram illustrating yet another example of the operation principle of the graphene photodetector according to the first embodiment.

FIG. 5A is a diagram illustrating an example of an operation principle of the graphene photodetector according to the first embodiment due to photovoltage generation.

FIG. 5B is a diagram illustrating an example of an operation principle of the graphene photodetector according to the first embodiment due to photocurrent generation.

FIG. 6 is a diagram illustrating results of a mapping measurement of visible light detection by the graphene photodetector according to the first embodiment.

FIG. 7 is a diagram illustrating results of a measurement of a visible light detection signal obtained by the graphene photodetector according to the first embodiment by a spectrum analyzer.

FIG. 8 is a diagram illustrating results of a mapping measurement of infrared light detection by the graphene photodetector according to the first embodiment.

FIG. 9 is a diagram illustrating results of a measurement of an infrared light detection signal obtained by the graphene photodetector according to the first embodiment by the spectrum analyzer.

FIG. 10 is a diagram illustrating a basic configuration according to a second embodiment.

FIG. 11A is an image of a graphene photodetector according to the second embodiment captured by the optical microscope.

FIG. 11B is a cross-sectional view schematically illustrating the graphene photodetector according to the second embodiment.

FIG. 12 is a diagram illustrating results of a mapping measurement of visible light detection by the graphene photodetector according to the second embodiment.

FIG. 13 is a diagram illustrating results of a measurement of a visible light detection signal obtained by the graphene photodetector according to the second embodiment by the spectrum analyzer.

FIG. 14 is a diagram illustrating results of a mapping measurement of infrared light detection by the graphene photodetector according to the second embodiment.

FIG. 15 is a diagram illustrating results of a measurement of an infrared light detection signal obtained by the graphene photodetector according to the second embodiment by the spectrum analyzer.

FIG. 16 is a diagram schematically illustrating an array of photodetectors in which graphene photodetectors according to the embodiments are arranged in two dimensions.

### MODE FOR CARRYING OUT THE INVENTION

An embodiment will provide a graphene photodetector, in which a pair of electrodes connected to a graphene film is formed of the same type of material, thus allowing a structure of the electrodes is asymmetric, so that light can be detected without collecting light. The “structure” of the electrode includes a shape and configuration of the electrode and a periphery of the electrode. The embodiment of the present invention will be described with reference to the drawings.

<First Embodiment>

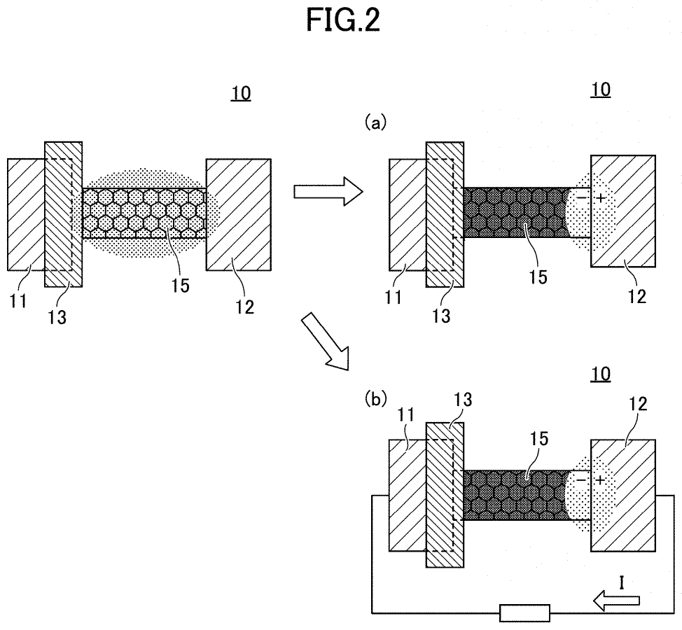

FIG. 2 is a diagram illustrating a basic configuration according to a first embodiment. In the first embodiment, a light shielding mask is provided only above an interface between one of a pair of electrodes and the graphene film to shield an incidence of light so that a configuration around the electrodes is made asymmetric.

A graphene photodetector 10 includes a pair of electrodes 11 and 12; a graphene film 15 disposed between the electrodes; and a light shielding mask 13 covering an interface between one electrode (e.g., electrode 11) and the graphene film 15 and a proximity of the interface. The electrodes 11 and 12 are formed of the same material. The light shielding mask 13 is arranged on a side through which light enters the graphene photodetector 10, and is arranged above the interface between one electrode 11 and the graphene film 15, for example, when viewed in a lamination direction of the photodetector.

Even when the entire graphene photodetector 10 is irradiated, the light shielding mask 13 blocks an incidence of light on a graphene portion located near the electrode 11 and a photovoltage is not generated at the interface between the electrode 11 and the graphene film 15. On the other hand, light enters the other portion of the graphene photodetector 10 and generates a photovoltage at the interface between the electrode 12 and the graphene film 15, as shown in (a) of FIG. 2. In the figure, the photovoltage is depicted as a potential difference between the positive side and the negative side. By detecting this photovoltage, an amount of the incident light can be measured.

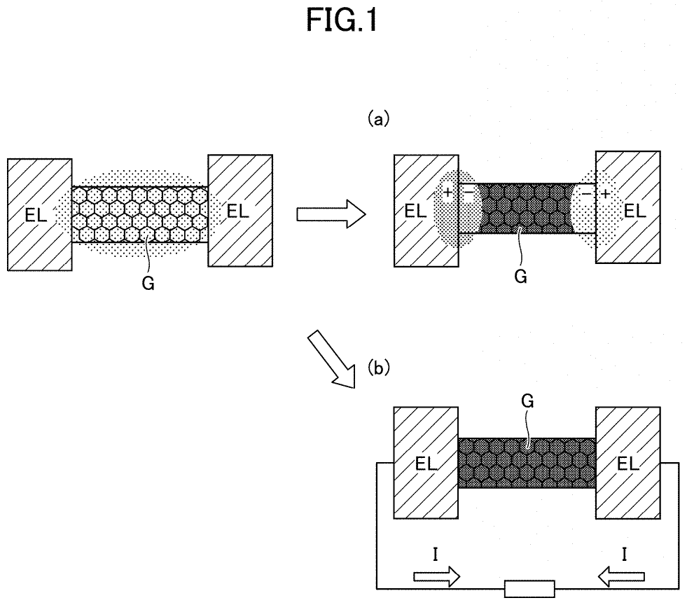

Here, the photovoltage generated in the graphene photodetector 10 includes a photovoltage generated by the temperature gradient generated in the vicinity of the graphene film-electrode interface when irradiated with light (photovoltage due to the thermoelectric effect). In the absence of the light shielding mask 13, the temperature gradients at the graphene film-electrode interfaces are opposite to each other, thus allowing the polarities of generated photovoltages are opposite to each other, as shown in (a) of FIG. 1. In the first embodiment, by providing the light shielding mask 13 at one graphene film-electrode interface, a photovoltage can be detected even when a temperature gradient is generated in the vicinity of the graphene film-electrode interface. In the following context, a “photovoltage” includes both a photovoltage due to an electron-hole pair creation and a photovoltage due to the thermoelectric effect.

When the graphene photodetector 10 is connected to a circuit, as shown in (b) of FIG. 2, electrons and holes generated by light absorption move along a gradient of the band at the interface between the electrode 12 and the graphene film 15, thus allowing a photocurrent flows in a direction of an arrow I. By observing the photocurrent, an amount of incident light can be measured. The photocurrent is also affected by the temperature gradient at the graphene film-electrode interface, but by the asymmetry according to the light shielding mask 13 cancellation of the photocurrents is suppressed. In the following context, a “photocurrent” includes both a photocurrent due to an electron-hole pair creation and a photocurrent due to the thermoelectric effect.

By introducing the structural asymmetry into the graphene photodetector 10, a difference occurs in the light receiving efficiency between the two electrode-graphene film interfaces, thus allowing the cancellation of photovoltages or photocurrents is suppressed. The graphene film 15 has a high electron mobility that is ten times greater than that of silicon, thus allowing can rapidly respond to a generation of a photovoltage or a photocurrent.

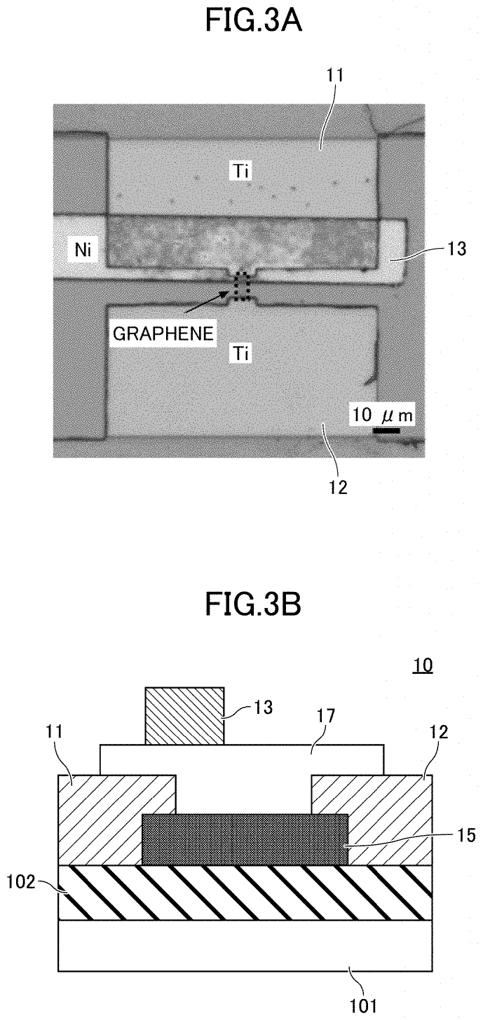

FIG. 3A is an image of the graphene photodetector 10 according to the first embodiment captured by an optical microscope, and FIG. 3B is a cross-sectional view schematically illustrating a light receiving region of the graphene photodetector 10. In the configuration example shown in FIG. 3A, the electrodes 11 and 12 are formed of the same metallic material, for example, titanium (Ti). A graphene film (referred to as “Graphene” in the figure) is electrically connected the electrode 11 and to the electrode 12.

A light shielding mask 13 of nickel (Ni) is disposed over the interface between one electrode 11 and the graphene film 15. Instead of the light-reflective metal mask such as Ni, a light shielding mask 13 may be formed of a material, such as a semiconductor or insulator that absorbs light.

FIG. 3B shows that the graphene film 15 is disposed on an insulation film 102 formed on the substrate 101. The substrate 101 is any substrate capable of supporting the graphene photodetector 10, such as a semiconductor substrate, a ceramic substrate, a glass substrate, or a quartz substrate.

The insulation film 102 is, for example, a silicon oxide film. The graphene film 15 may be formed and patterned directly on the insulation film 102, by a CVD process, for example. Alternatively, a graphene film grown on another substrate may be peeled off by a mechanical stripping process and transferred onto the insulation film 102.

The electrode 11 and the electrode 12 are connected to the graphene film 15. The electrodes 11 and 12 may be formed of any electrode material that is a good conductor, and V, Pd, Pt, Au, Ag, Ir, Mo, Ru, Cu, Al, or the like is used in addition to Ti. The electrodes 11 and 12 need not necessarily be disposed on an upper side of the graphene film 15 in a lamination direction, but a thin film of the graphene film 15 may be disposed on the electrodes 11 and 12.

The light shielding mask 13 covers the interface between the electrode 11 and the graphene film 15. When the light shielding mask 13 is formed of a metal or a semiconductor, an insulation film 17 is inserted between the light shielding mask 13 and each of the electrodes 11, 12 and the graphene film 15. Thus, a bypass of current to the light shielding mask 13 can be suppressed. The insulation film 17 may be formed of an inorganic material or of an organic material as long as it has an electrical insulation property. For example, the insulation film 17 is formed of aluminum oxide (Al₂O₃).

A variety of metals such as Ni, Ti, Pd, Au, Al, Cr, and Cu can be used when the light shielding mask 13 is formed of a metal that reflects light having a certain wavelength. When the light shielding mask 13 is formed of a semiconductor which does not transmit light having the certain wavelength, Si, Ge, an oxide semiconductor, or the like may be used.

When the light shielding mask 13 is formed of an insulator that is opaque to light having the certain wavelength, the light shielding mask 13 may be disposed directly on the electrode 11. In this case, the light shielding mask 13 is provided so as to cover the interface region between the electrode 11 and the graphene film 15. Quartz may be used as the insulator to absorb light having the certain wavelength. The light shielding mask 13 is not limited to a film of an inorganic material and may be formed of a polymer material such as resist as long as it is opaque to light having the certain wavelength.

By providing the light shielding mask 13 that covers only the interface between one electrode 11 and the graphene film 15, as shown in FIGS. 3A and 3B, the electrode-graphene film interfaces become structurally asymmetric and can suppress cancellation of photovoltages or photocurrents between the electrodes.

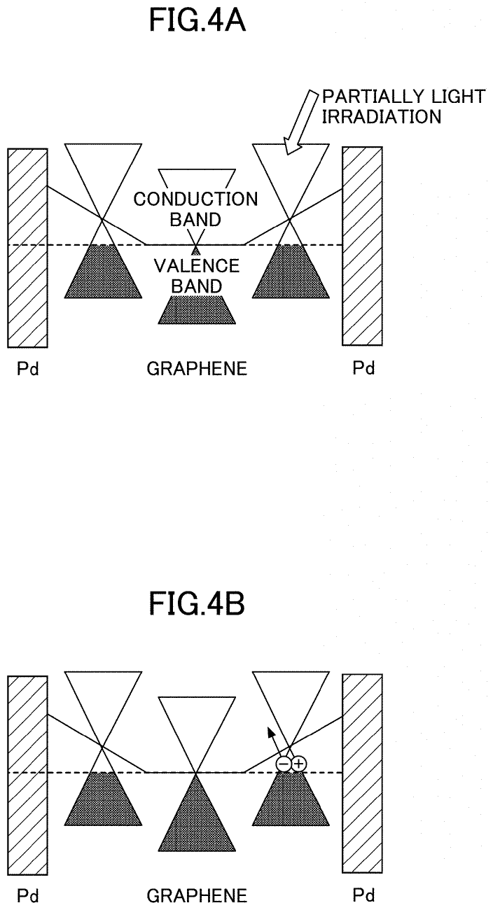

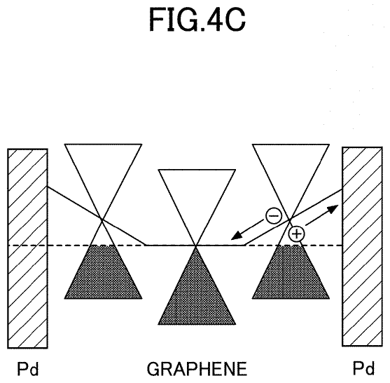

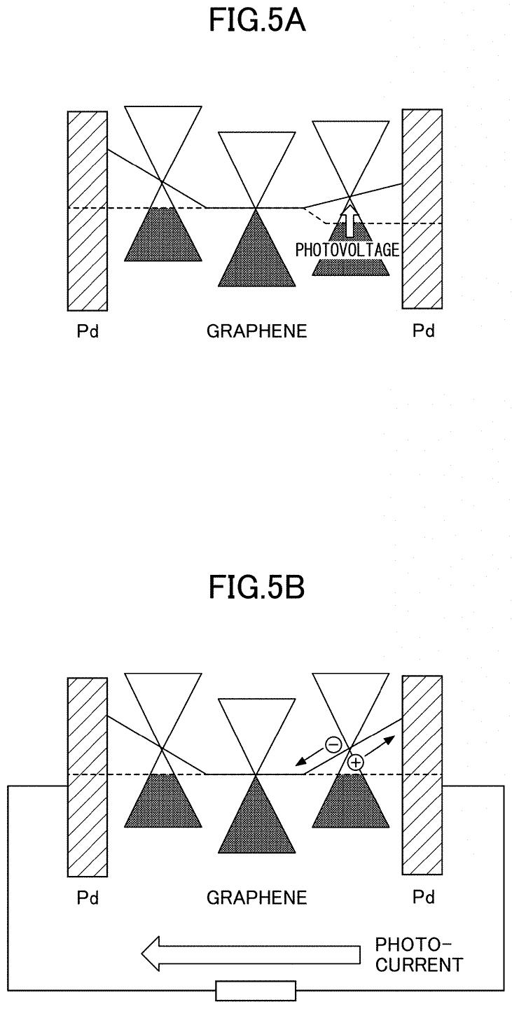

FIGS. 4A to 4C, FIGS. 5A and 5B illustrate the principle of operation of the graphene photodetector 10. The conduction and valence bands of graphene can be simulated by symmetric cones where vertices abut at the Dirac point (point K or point K′ in the wavenumber space). Because the conduction and valence bands intersect at the Dirac point and a band gap is absent, the graphene film can absorb light with even low energy in the infrared region. In other words, the graphene film absorbs a wide range of light with wavelength from infrared light to ultraviolet light.

As shown in FIG. 4A, at the interface between metal (e.g., Pd) and a graphene film, an energy band gradient is created. In the configuration in which the graphene film is positioned between the pair of electrodes, the gradients of the bands between the electrodes are opposite to each other. In the first embodiment, the electrodes of the graphene photodetector 10 have an asymmetric structure. Even if the entire graphene photodetector 10 is irradiated, an interface between one electrode and the graphene film is partially irradiated.

At the interface between one electrode and the graphene film, electrons receive energy from the incident light and are excited from the valence band to the conduction band, as shown in FIG. 4B. Holes are left in the valence band. As shown in FIG. 4C, the carrier moves along the gradient of the energy band.

As shown in FIG. 5A, when the graphene photodetector 10 is not connected to a circuit, a potential difference occurs at the graphene-metal interface, thus allowing a bend of the band changes as shown by a dashed line. The generated voltage is called a photovoltage. By detecting the photovoltage, an amount of the incident light can be detected.

As shown in FIG. 5B, when the graphene photodetector is connected to a circuit, the electrons excited into the conduction band circulate around the circuit along the gradient of the band to produce a current. This current is called a photocurrent. Only at the interface between one electrode and the graphene film carriers move, so the cancellation of photocurrents between the electrodes is suppressed and incident light can be detected with high sensitivity. As described above, a photovoltage and a photocurrent can also be caused by the thermoelectric effect due to temperature gradients near the electrode-graphene film interfaces caused by irradiation of light. According to the asymmetry of the present invention, the cancellation of photovoltages or photocurrents due to the thermoelectric effect is also suppressed and light can be detected.

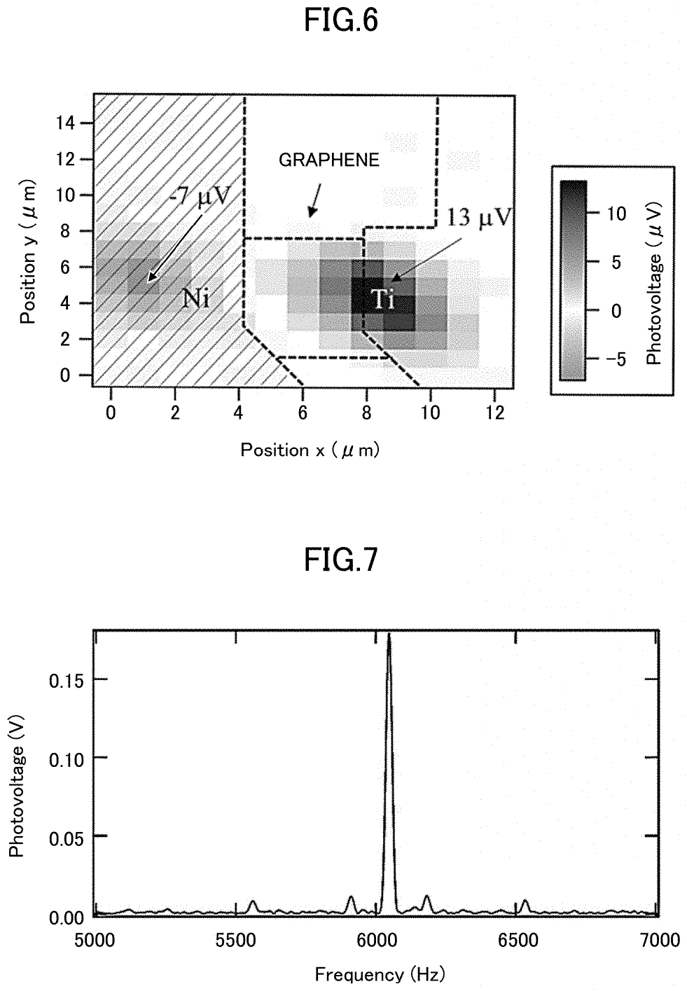

FIG. 6 shows results of a mapping measurement of visible light detection by the fabricated graphene photodetector 10. The mapping measurement is used to determine which part of the fabricated asymmetric graphene photodetector 10 obtains a photovoltage (position dependence of the photovoltage).

In the measurement shown in FIG. 6, laser light with a wavelength of 690 nm in the visible light region is collected by an objective lens, collected light is scanned, and a photovoltage value generated at each scanning point is mapped. At an interface between the Ti electrode and the graphene film on the side without the light shielding mask, a photovoltage of +13 μV is measured, and the voltage decreases as the scanning point is separated from the interface.

On the side with the Ni shielding mask, a photovoltage of −7 μV is measured at the interface between the Ti electrode and the graphene film. As the scanning point is separated from the interface, the magnitude (absolute value) of the photovoltage decreases.

A photovoltage of the opposite polarity is measured on the side with the Ni mask, because a part of the incident light passed through the Ni mask and reached the graphene film-electrode interface. However, even in this case, the magnitude (absolute value) of the photovoltage generated on the Ni mask side is about half the magnitude (absolute value) of the photovoltage generated at the graphene film-electrode interface on the opposite side, so that the cancellation of photovoltages can be suppressed.

FIG. 7 shows results of measurement of a spectrum analyzer for a visible light detection signal obtained by the graphene photodetector 10. Different from the confirmation of the position-dependence of photovoltage shown in FIG. 6, the entire graphene photodetector 10 is irradiated and a detection signal output from the graphene photodetector 10 is measured. It is confirmed that according to the asymmetric configuration shown in FIGS. 3A and 3B, visible light can be detected, even when the entire graphene photodetector 10 is irradiated without collecting light.

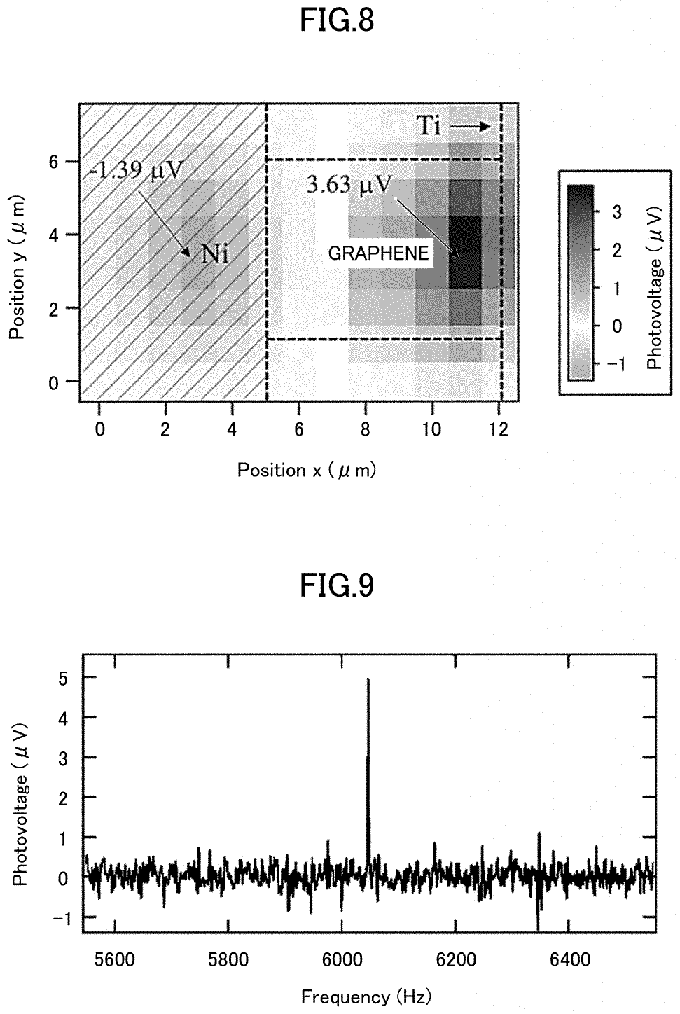

FIG. 8 shows results of the mapping measurement of infrared light detection by the graphene photodetector 10. Laser light with a wavelength of 1310 nm in the infrared region is collected by the objective lens, the collected light is scanned, and a photovoltage value generated at each scanning point is mapped. At the interface between the Ti electrode and the graphene film on the side without the light shielding mask, a photovoltage of +3.63 μV is measured, and the voltage decreases as the scanning point is separated from the interface.

On the side with the Ni shielding mask, a photovoltage of −1.39 μV is measured at the interface between the Ti electrode and the graphene film. As the scanning point is separated from the interface, the magnitude (absolute value) of the photovoltage decreases.

A photovoltage of the opposite polarity is measured on the side with the Ni mask, because a part of the infrared light passed through the Ni mask and reached the graphene film-electrode interface. However, even in this case, the magnitude (absolute value) of the photovoltage generated on the Ni mask side is less than 40% of the magnitude (absolute value) of the photovoltage generated at the graphene film-electrode interface on the opposite side, so that the cancellation of photovoltages can be suppressed.

FIG. 9 shows results of measurement of the spectrum analyzer for an infrared light detection signal obtained with the graphene photodetector 10. Different from the confirmation of the position-dependence of photovoltage shown in FIG. 8, the entire graphene photodetector 10 is irradiated with infrared light (laser light with a wavelength of 1547 nm) to measure the infrared light detection signal output from the graphene photodetector 10. It is confirmed that according to the asymmetric configuration shown in FIGS. 3A and 3B, infrared light can be detected, even when the entire graphene photodetector 10 is irradiated without collecting light.

Thus, according to the asymmetric structure in which only the interface between one electrode and the graphene film is covered with the light shielding mask 13, light with wavelength over a wide range that covers ultraviolet light to infrared light, and even the terahertz band, can be detected without light collection.

<Second embodiment>

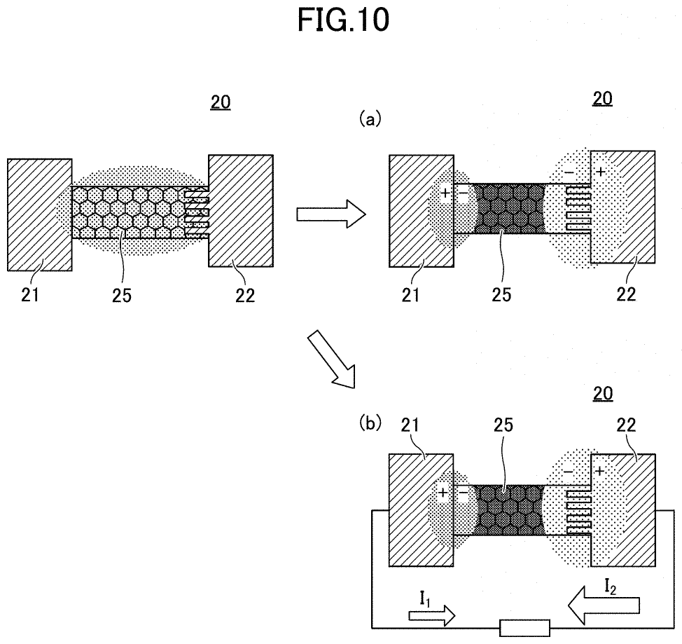

FIG. 10 is a diagram illustrating a basic configuration of a second embodiment. In the second embodiment, a shape of the electrodes is made asymmetric by setting a contact area of one electrode with the graphene film greater than that of the other electrode.

A graphene photodetector 20 includes a pair of electrodes 21 and 22; and graphene film 25 disposed between the electrodes. The electrodes 21 and 22 are formed of the same material but have different planar shapes. Since the electrodes 21 and 22 can be formed simultaneously in the same process, there is no increase in the fabrication process.

The electrode 22 has a plurality of comb teeth and may be designed to have the contact area at the interface with the graphene film 25 greater than the contact area at the interface between the electrode 21 and the graphene film 25. In this case, when the entire graphene photodetector 20 is irradiated, the photovoltage generated at the interface between the electrode 22 and the graphene film 25 is greater than the photovoltage generated at the interface between the electrode 21 and the graphene film 25, as shown in (a) of FIG. 10. In the figure, the photovoltage is depicted as a voltage difference between a voltage on the plus side and a voltage on the minus side. Although the polarities of the photovoltages generated at the two electrode-graphene film interfaces are opposite to each other, magnitudes (absolute values) of the photovoltages are different from each other, thus allowing photovoltage can be detected.

When the graphene photodetector 20 is connected to a circuit as in (b) of FIG. 10, electrons and holes generated by the light absorption move along the gradient of the band at the electrode-graphene film interface. The electrons generated at the interface between the electrode 21 and the graphene film 25 move to the graphene film 25, and a photocurrent I₁ flows. The electrons generated at the interface between the electrode 22 and the graphene film 25 move to the graphene film 25, and a photocurrent 12 flows. Although directions of the photocurrents flowing are opposite to each other, a photocurrent can be observed because magnitudes of the photocurrents are different from each other.

By introducing the asymmetry into the electrode shape of the graphene photodetector 20, a difference occurs in the light receiving efficiency between the two electrode-graphene film interfaces, photovoltages or photocurrents are not cancelled, thus allowing a light detection signal can be obtained.

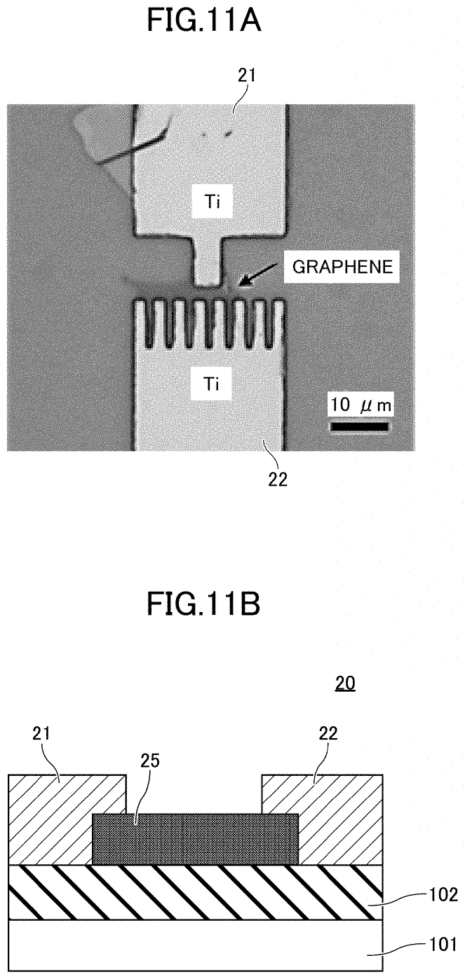

FIG. 11A is an image of the graphene photodetector 20 according to the second embodiment captured by an optical microscope, and FIG. 11B is a cross-sectional view schematically illustrating a light receiving region of the graphene photodetector 20. In the configuration example shown in FIG. 11A, the electrodes 21 and 22 are formed of the same metallic material, for example titanium (Ti). However, planar shapes of the electrodes at the interface with the graphene film are different from each other. The graphene film (designated “Graphene” in the figure) is in contact with the comb teeth of one electrode 22 and a tip of the other electrode 21.

FIG. 11B shows that the graphene film 25 is disposed on an insulation film 102 formed on a substrate 101. The substrate 101 is any substrate capable of supporting the graphene photodetector 20, such as a semiconductor substrate, a ceramic substrate, a glass substrate, or a quartz substrate.

The insulation film 102 is, for example, a silicon oxide film. The graphene film 25 may be formed and patterned directly on the insulation film 102, by a CVD process, for example. Alternatively, a graphene film grown on another substrate may be peeled off by a mechanical stripping process and transferred onto the insulation film 102.

The electrode 21 and the electrode 22 are connected to the graphene film 25. As can be seen in FIG. 11A, the electrode 22 is in contact with the graphene film 25 through the plurality of comb teeth. The electrode 21 is in contact with the graphene film 25 via the region having a projection shape thicker than the comb tooth of the electrode 22. Contact areas of the electrodes 21 and 22 with the graphene film 25 are different from each other. The electrodes 11 and 12 need not necessarily be disposed on an upper side of the graphene film 15 in the lamination direction, but a thin film of the graphene film 25 may be disposed over the electrodes 22 and 21 if it is disposed to cover the comb teeth at the tip of the electrode 22 and the projection at the tip of the electrode 21. The entire graphene photodetector 20 may be covered with an insulative transparent protection film that transmits light having the certain wavelength.

As shown in FIGS. 11A and 11B, the electrode-graphene film interfaces become asymmetric by making the area of the interface between one electrode 22 and the graphene film 25 different from the area of the interface between the other electrode 21 and the graphene film 25. The cancellation of photovoltages or photocurrents can be suppressed even when the entire graphene photodetector 20 is irradiated.

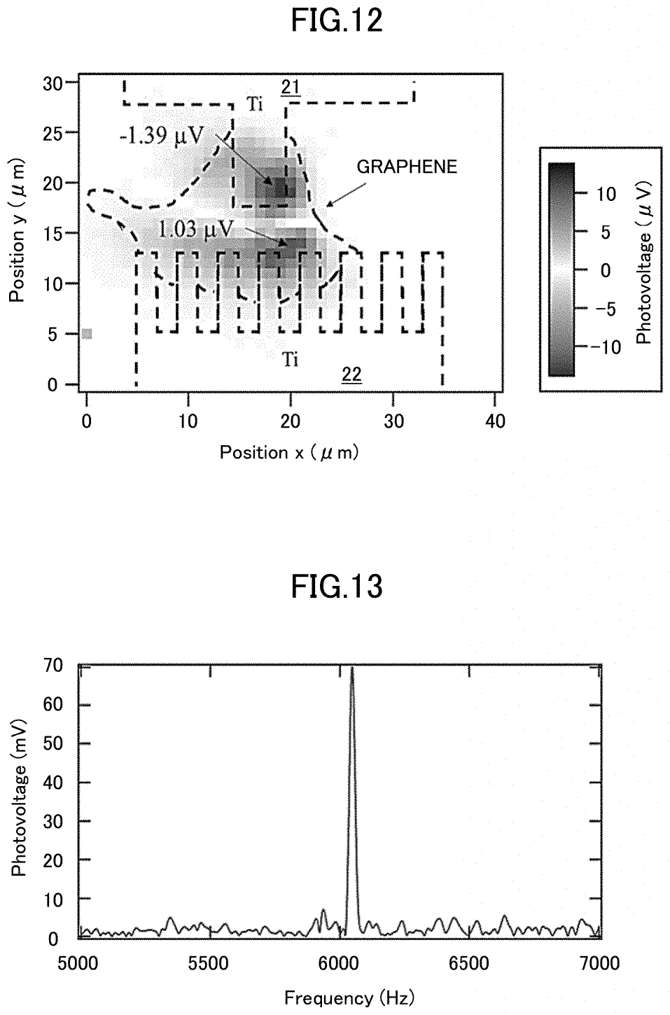

FIG. 12 shows results of a mapping measurement of visible light detection by the fabricated graphene photodetector 20. In the measurement shown in FIG. 12, in order to determine a generation position of a photovoltage, laser light with a wavelength of 690 nm in the visible light region is collected by the objective lens, collected light is scanned, and a photovoltage value at each scanning point is mapped. At the interface between the comb teeth of the electrode 22 and the graphene film 25, a photovoltage of +1.03 μV is measured, and the voltage decreases as the scanning point is separated from the interface. At the interface between the projection of the electrode 21 and the graphene film 25, a photovoltage of −1.39 μV is measured. The magnitude (absolute value) of the photovoltage decreases as the scanning point is separated from the interface.

In FIG. 12, the magnitudes of the photovoltaic forces at the electrodes 21 and 22 are not significantly different from each other because light is collected by the objective lens and spot irradiation is performed. However, when the entire photodetector is irradiated with light, the electrodes 21 and 22 have an asymmetry in an internal resistance of the graphene film and a contact resistance, and voltage drops are different from each other. By making the areas of the portions of the electrodes contacting the graphene film asymmetric, the cancellation of photovoltages is suppressed when the entire photodetector is irradiated with light, thus allowing the photovoltage can be detected.

FIG. 13 shows results of measurement of the spectrum analyzer for a visible light detection signal obtained by the graphene photodetector 20. Different from the confirmation of the position-dependence of photovoltage shown in FIG. 12, the entire graphene photodetector 20 is irradiated with light and a detection signal output from the graphene photodetector 20 is measured. It is confirmed that according to the asymmetric configuration shown in FIGS. 11A and 11B, visible light can be detected, even when the entire graphene photodetector 20 is irradiated without collecting light.

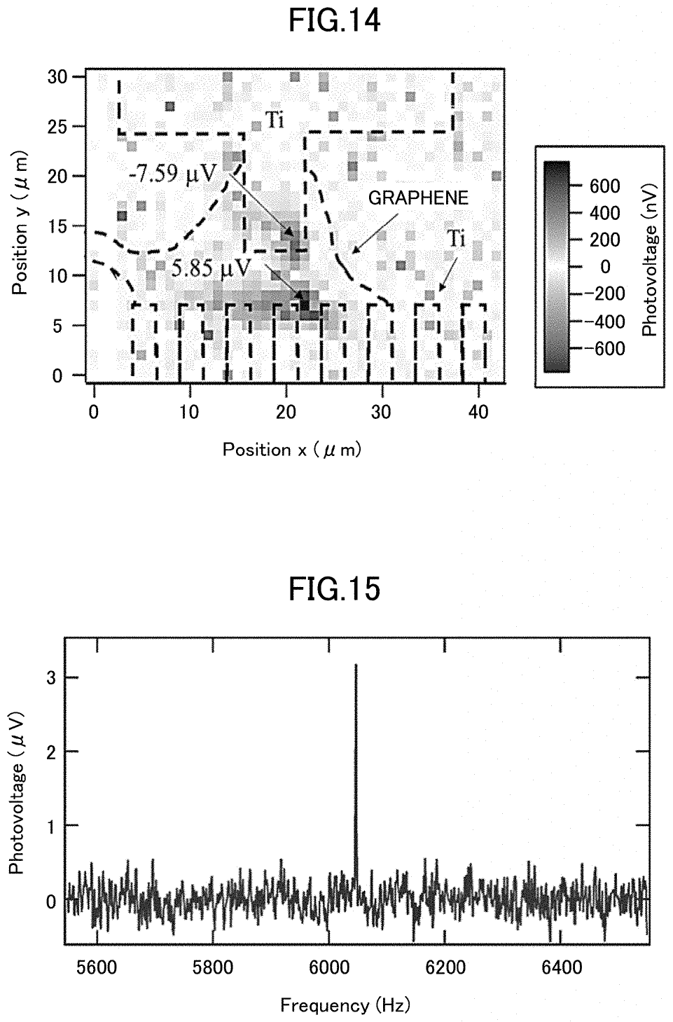

FIG. 14 shows results of the mapping measurement of infrared light detection by the graphene photodetector 20. Laser light with a wavelength of 1310 nm in the infrared region is collected by the objective lens, the collected light is scanned, and a photovoltage value generated at each scanning point is mapped. At the interface between the comb teeth of the electrode 22 and the graphene film, a photovoltage of +5.85 μV is measured, and at the interface between the projection of the electrode 21 and the graphene film, a photovoltage of −7.59 μV is measured. As the scanning points are separated from the interfaces, the magnitudes (absolute values) of the photovoltages decrease, respectively.

In FIG. 14, the magnitudes of the photovoltaic forces at the electrodes 21 and 22 are not significantly different from each other because light is collected by the objective lens and spot irradiation is performed. However, when the entire photodetector is irradiated with light, the electrodes 21 and 22 have an asymmetry in an internal resistance of the graphene film and a contact resistance, thus allowing voltage drops are different from each other. By making the areas of the portions of the electrodes contacting the graphene film asymmetric, the cancellation of photovoltages is suppressed when the entire photodetector is irradiated with infrared light, thus allowing the photovoltage can be detected.

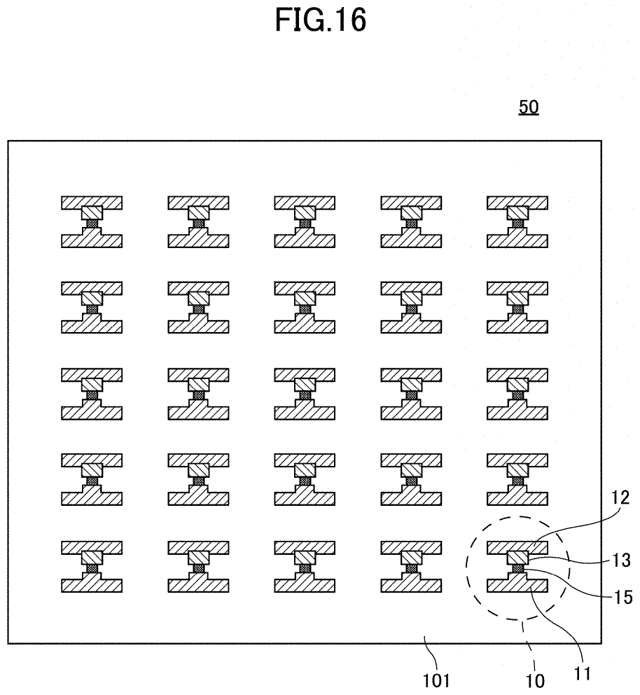

FIG. 15 shows results of measurement of the spectrum analyzer for an infrared light detection signal obtained by the graphene photodetector 20. Different from the confirmation of the position-dependence of photovoltage shown in FIG. 14, the entire graphene photodetector 20 is irradiated with infrared light (laser light with a wavelength of 1547 nm), and an infrared light detection signal output from the graphene photodetector 20 is measured. A sharp peak is observed in the output signal. It is confirmed that according to the asymmetric configuration shown in FIGS. 11A and 11B, infrared light can be detected, even when the entire graphene photodetector 20 is irradiated without collecting light.

Similar to the first embodiment, results of the measurement have been shown for wavelengths of visible light and near infrared light. However, the photodetector according to the second embodiment can be actually applied to detection of light with wavelength of a very wide range covering from the ultraviolet region to the infrared region and even the terahertz region.

<Other configurations>

The configuration of the first embodiment and the configuration of the second embodiment may be combined. For example, as in the second embodiment, the areas of the interfaces of the electrodes in contact with the graphene film may be made asymmetric, and the electrode with the smaller interface area may be provided with a light shielding mask. In this case, the difference between the photovoltages generated at the two electrodes or the magnitudes of the flowing photocurrents increases, thus allowing the detection sensitivity is further improved.

When the areas or the planar shapes of the interfaces between the electrodes and the graphene film are made asymmetric, the shape is not limited to the comb teeth shape. One electrode may have any shape that can increase the contact area with the graphene film, such as a corrugate shape, or a saw teeth shape. In this case also, asymmetric electrodes can be easily formed in a single step.

Through the first embodiment and the second embodiment, an optical system for collecting light, such as an objective lens, is not required to be arranged, thus allowing the structure of the graphene photodetector is simplified. Further, in the photodetector controlled by the work function, there are few choices of materials of the pair of electrodes that are different from each other, and there are problems in cost and durability. However, the embodiment of the present application has a high degree of freedom of selecting the materials, thus allowing it is possible to fabricate the graphene photodetector having a simple structure with low cost.

FIG. 16 is a plan view schematically illustrating a photodetector array 50 using the graphene photodetectors according to the embodiments of the present application. On a substrate 101, for example, the graphene photodetectors 10 according to the first embodiment are disposed two-dimensionally. Moreover, the graphene photodetectors 20 according to the second embodiment may be disposed two-dimensionally. The photodetector array 50 functions as a two-dimensional imaging device.

Light in the infrared region is invisible to the naked eye. Currently available infrared cameras include photodetectors made of compound semiconductors and are extremely expensive. Moreover, in order to fabricate a photodetector array with the conventional graphene photodetectors, it is necessary to provide a light collecting mechanism corresponding to each of the graphene photodetectors. However, it is difficult to converge light only at an electrode-graphene film interface of the small graphene photodetector. On the other hand, the configuration according to the embodiment of the present application does not require a condenser lens, thus allowing an infrared imaging device can be fabricated in a simple configuration.

Imaging in the infrared region is attracting attention because of its wide range of applications, including night vision cameras, cameras for automatic operation, and the like. The currently used non-cooling type imaging in the infrared region uses mainly bolometer type imaging devices, which is inefficient, complicated in structure, and expensive. The quantum-type infrared sensing elements are easily affected by a thermal noise, require cooling, and are difficult to reduce cost and size. The graphene photodetector and the photodetector array according to the embodiments of the present application operate at room temperature, are easy to integrate, thus allowing a small-sized imaging device can be provided at low cost.

The present application is based on and claims priority to Japanese patent application No. 2019-178844 filed Sep. 30, 2019, with the Japanese patent office, the entire contents of which are hereby incorporated by reference.

REFERENCE SIGNS LIST

| | |
|---|---|
| 10, 20 | Graphene photodetector |
| 11, 12, 21, 22 | Electrode |
| 13 | Light shielding mask |
| 15, 25 | Graphene film |
| 50 | Photodetector array |

1. A graphene photodetector comprising:
a first electrode;
a second electrode; and
a graphene film electrically connected the first electrode and to the second electrode, wherein
a first interface region of the first electrode and a second interface region of the second electrode have an asymmetric structure in interface regions with the graphene film, the first interface region and the second interface region being regions of the first electrode and the second electrode, respectively that are formed of the same conductive material.

2. The graphene photodetector according to claim 1, wherein
either the first electrode in the first interface region or the second electrode in the second interface region is covered with a light shielding mask.

3. The graphene photodetector according to claim 2, wherein
the light shielding mask is formed of an insulative material opaque to light having a certain wavelength.

4. The graphene photodetector according to claim 2, wherein
the light shielding mask is foimed of a light reflective metal or a semiconductor opaque to light having a certain wavelength, and
the light shielding mask is placed on the insulation layer, and the portion of the insulation where the mask is located is then positioned over either of the electrodes.

5. The graphene photodetector according to claim 1, wherein
a planar shape of the first electrode in the first interface region and a planar shape of the second electrode in the second interface region are different from each other.

6. The graphene photodetector according to claim 1, wherein
an area of the first electrode in the first interface region and an area of the second electrode in the second interface region are different from each other.

7. The graphene photodetector according to claim 6, wherein
a light shielding mask is disposed on an electrode, from among the first electrode and the second electrode, having the interface region with a smaller area.

8. A photodetector array comprising:
a plurality of graphene photodetectors according to claim 1 disposed in a coplanar arrangement.
